(19) United States
(12) Patent Application Publication
(10) Pub. No.: US 2019/0259635 A1
(43) Pub. Date: Aug. 22, 2019

(54) PROCESS KIT FOR PROCESSING REDUCED SIZED SUBSTRATES

(71) Applicant: APPLIED MATERIALS, INC., Santa Clara, CA (US)

(72) Inventors: KARRTHIK PARATHITHASAN, Singapore (SG); FANG JIE LIM, Singapore (SG); ANAND MAHADEV, Bangalore (IN); SHOJU VAYYAPRON, Bangalore (IN); SRISKANTHARAJAH THIRUNAVUKARASU, Singapore (SG); ENG SHENG PEH, Singapore (SG)

(21) Appl. No.: 16/273,390

(22) Filed: Feb. 12, 2019

Related U.S. Application Data
(60) Provisional application No. 62/631,672, filed on Feb. 17, 2018.

(51) Int. Cl. H01L 21/673; H01L 21/02; H01L 21/683

(52) U.S. Cl. CPC H01L 21/673; H01L 21/683; H01L 21/02266

(57) ABSTRACT

Embodiments of a process kit for processing reduced size substrates are provided herein. In some embodiments, a process kit includes a substrate carrier having a pocket configured to hold a substrate, wherein the pocket extends partially through a thickness of the substrate carrier; and wherein the pocket includes an annular trench disposed at a periphery of a floor of the pocket.

### CROSS-REFERENCE TO RELATED APPLICATIONS

This application claims benefit of U.S. provisional patent application Ser. No. 62/631,672, filed Feb. 17, 2018, which is herein incorporated by reference in its entirety.

### FIELD

Embodiments of the present disclosure generally relate to substrate processing equipment.

### BACKGROUND

With the advancement of technologies and more compact, smaller electronic devices with high computing power, industries have shifted their focus from 200 mm to 300 mm wafers. As processing of 300 mm wafers becomes more dominant in the market, demand for tools with 300 mm processing capabilities increases, leading tool manufacturers to design and build more 300 mm tools, slowly phasing out 200 mm tools.

However, despite the transition to 300 mm substrate processing, many chipmakers still have a large quantity of 200 mm substrates in their respective inventories. The inventors believe that such chipmakers and others with a desire to process 200 mm substrates, may not wish to purchase 200 mm tools that may soon be obsolete.

Therefore, the inventors have provided a process kit for processing reduced size substrates.

### SUMMARY

Embodiments of a process kit for processing reduced size substrates are provided herein. In some embodiments, a process kit includes a substrate carrier having a pocket configured to hold a substrate, wherein the pocket extends partially through a thickness of the substrate carrier, and wherein the pocket includes an annular trench disposed at a periphery of a floor of the pocket.

In some embodiments, a process kit includes a substrate carrier having a pocket configured to hold a substrate that extends partially through a thickness of the substrate carrier and having an uppermost surface that includes an annular upwardly extending protrusion; and a shadow ring disposed above the substrate carrier to shield a portion of the substrate carrier radially outward of the pocket and having an annular recess in a lower surface corresponding with the annular upwardly extending protrusion of the substrate carrier, and wherein an inner diameter of the shadow ring is less than an outer diameter of the pocket.

In some embodiments, a processing chamber includes a substrate support having a support surface; a substrate carrier disposed atop the support surface, the substrate carrier having a pocket configured to hold a substrate; a shadow ring disposed atop the substrate carrier to shield a portion of the substrate carrier radially outward of the pocket; and a process kit having a process kit shield disposed about the substrate carrier and the shadow ring to define a processing volume above the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A is a schematic top view of a substrate carrier in accordance with some embodiments of the present disclosure.

FIG. 1B is a cross-sectional view of the substrate carrier of FIG. 1A taken along line B-B′.

FIG. 2A is a schematic top view of a shadow ring in accordance with some embodiments of the present disclosure.

FIG. 2B is a cross-sectional view of the shadow ring of FIG. 2A taken along line B-B′.

FIG. 3A is a schematic top view of a deposition ring in accordance with some embodiments of the present disclosure.

FIG. 3B is a cross-sectional view of the deposition ring of FIG. 3A taken along line B-B′.

FIG. 4 is a plan view of a multi-chamber cluster tool suitable for processing of different size substrates in accordance with some embodiments of the present disclosure.

FIG. 5 depicts a schematic cross-sectional view of a processing chamber having a process kit in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present disclosure generally relate to a process kit for processing reduced size substrates. Specifically, embodiments of the present disclosure provide a means for processing of 200 mm substrates using 300 mm tools while maintaining the capability of those tools to still handle 300 mm substrates. Switching between the 200 mm and the 300 mm functionalities are reversible and can be selected from a user interference without any hardware modification, thus advantageously reducing or eliminating any downtime.

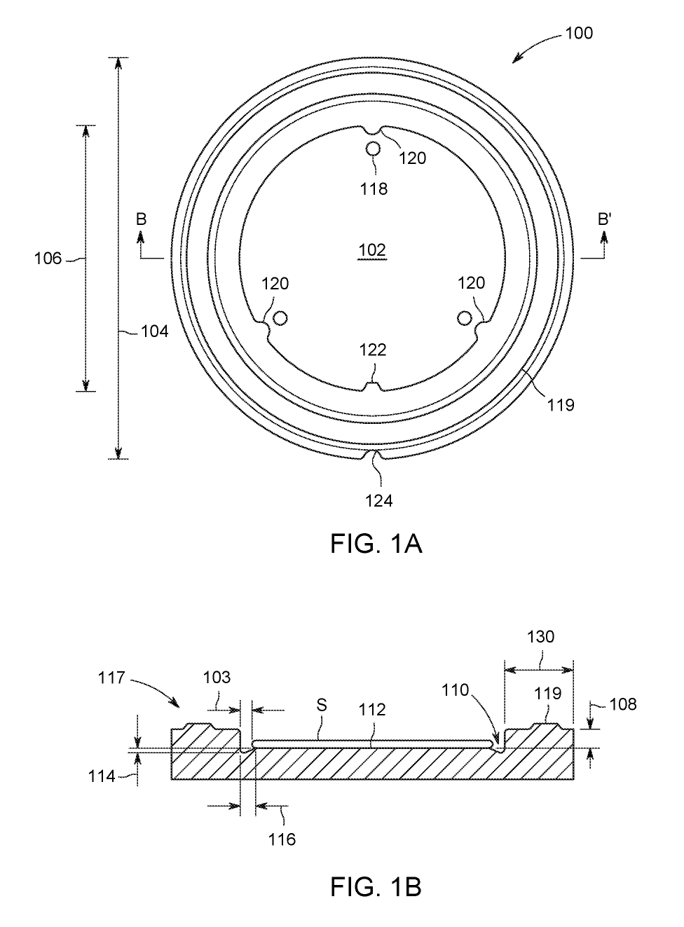

The inventive process kit includes a substrate carrier 100 and a shadow ring 200. A deposition ring 300 having protrusions for supporting the shadow ring 200 may also be utilized to support the shadow ring 200 above the substrate carrier 100 during processing of a reduced size (e.g., 200 mm) substrate. The following description of the substrate carrier 100 will be made with references to FIGS. 1A and 1B. FIG. 1A is a schematic top view of the substrate carrier 100 in accordance with some embodiments of the present disclosure. FIG. 1B is a cross-section view of the substrate carrier 100 taken along line B-B′.

The substrate carrier 100 is formed of a dielectric material such as, for example, monosilicon quartz, ceramic, silicon carbide having a purity of 99% or greater. The substrate carrier 100 includes a body and a pocket 102 configured to hold a substrate S. In some embodiments, the substrate S may be a 200 mm substrate. The pocket 102 extends partially through a thickness of the substrate carrier 100. To enable the processing of the 200 mm substrate in a chamber configured to process 300 mm substrates, the size of the substrate carrier 100 mimics a 300 mm substrate. That is, a diameter 104 of the substrate carrier 100 is about 300 mm. In some embodiments, a diameter 106 of the pocket 102 is between about 200 mm and about 210 mm. In some embodiments, a spacing 103 between an edge of the substrate S and the walls of the pocket 102 is at least 0.25 mm. In some embodiments, a depth 108 of the pocket 102 from an upper surface of the substrate carrier 100 to a floor 112 of the pocket 102 is between about 0.5 mm and about 0.7 mm.

In some embodiments, the pocket 102 includes an annular trench 110 disposed at the periphery of the floor 112 of the pocket 102 to prevent backside deposition on the substrate S and prevent arcing between substrate S and any deposited material within the pocket 102. In some embodiments, a depth 114 of the annular trench 110 is between about 0.2 mm and about 0.6 mm. In some embodiments, the depth 114 is about 0.4 mm. In some embodiments, a cross-sectional width 116 of the annular trench 110 is about 0.8 mm to about 1.2 mm. In some embodiments, the cross-sectional width 116 of the annular trench 110 is about 1 mm.

In some embodiments, an uppermost surface 117 of the substrate carrier is configured to mate with a bottom surface of the shadow ring 200 (discussed below). The uppermost surface 117 includes an annular upwardly extending protrusion 119 that is configured to be disposed within a corresponding annular recess formed in the bottom surface of the shadow ring 200.

In some embodiments, the substrate carrier 100 may include a plurality of lift pin holes 118 through which a corresponding plurality of lift pins (not shown) may extend to receive the substrate S and lower/lift the substrate S into/out of the pocket 102. In some embodiments, the substrate carrier 100 may further include at least one protrusion 120 (three shown in FIG. 1A) extending radially inward into the pocket 102 to prevent, or limit, the substrate S from moving around during handling of the substrate carrier 100 (e.g., by a transfer robot). In some embodiments, the at least one protrusion extends into the pocket 102 between about 0.2 mm and about 0.5 mm.

In some embodiments, the substrate carrier 100 may also include an alignment feature 122 that extends into the pocket 102 by about 1 mm. The alignment feature 122 is configured to extend into a corresponding notch (not shown) in the substrate S to correctly align the substrate S with respect to the substrate carrier 100. In some embodiments, the substrate carrier 100 may include a similar notch 124 that is configured to receive a corresponding alignment feature (not shown) of a substrate support to correctly align the substrate carrier 100 with respect to the substrate support.

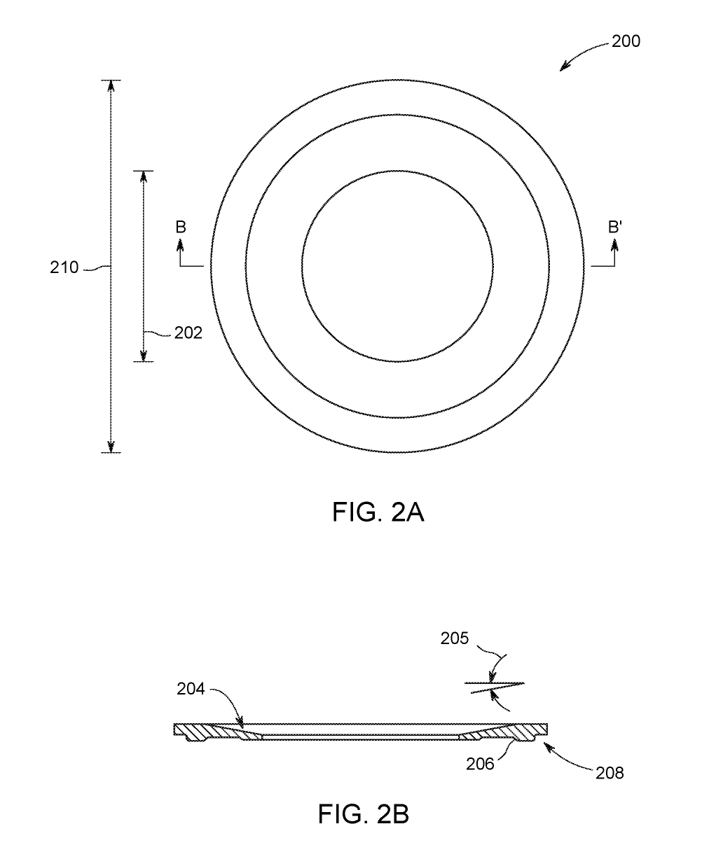

The following description of the shadow ring 200 will be made with reference to FIGS. 2A and 2B. FIG. 2A is a schematic top view of the shadow ring 200 in accordance with some embodiments of the present disclosure. FIG. 2B is a cross-section view of the shadow ring 200 taken along line B-B′. The shadow ring 200 is formed of a dielectric material having a high thermal conductivity such as, for example, quartz or ceramic having a purity of 99% or greater. In some embodiments, an inner diameter 202 of the shadow ring 200 is between 0.2 mm and about 0.4 mm less than the diameter 106 of the pocket 102 (i.e., between about 199.6 mm and about 209.8 mm) to minimize deposition in the annular trench 110. In some embodiments, an upper surface 204 of the shadow ring 200 has a horizontal outer portion and a sloped inner portion. The sloped inner portion includes a surface having a gradient 205 (e.g., surface disposed at an angle from a horizontal plane of the shadow ring). In some embodiments, the gradient 205 is between about 2.5° and about 3.1°. The inventors have discovered that a gradient less than about 2.5° would result in more deposition at a bevel (not shown) of the substrate S and a gradient greater than about 3.1° would result in non-uniform deposition at an edge of the substrate S.

The shadow ring 200 is configured to be disposed above the substrate carrier 100 to shield a portion 130 (see FIG. 1) of the substrate carrier 100 radially outward of the pocket 102. An annular recess 206 is formed in a lower surface of the shadow ring 200 to mate with the annular upwardly extending protrusion 119 of the substrate carrier 100 when the shadow ring 200 is disposed above the substrate carrier 100. The shadow ring 200 further includes a ledge 208 disposed radially outward of the annular recess 206 which rests on protrusions of the deposition ring 300, as will be discussed below.

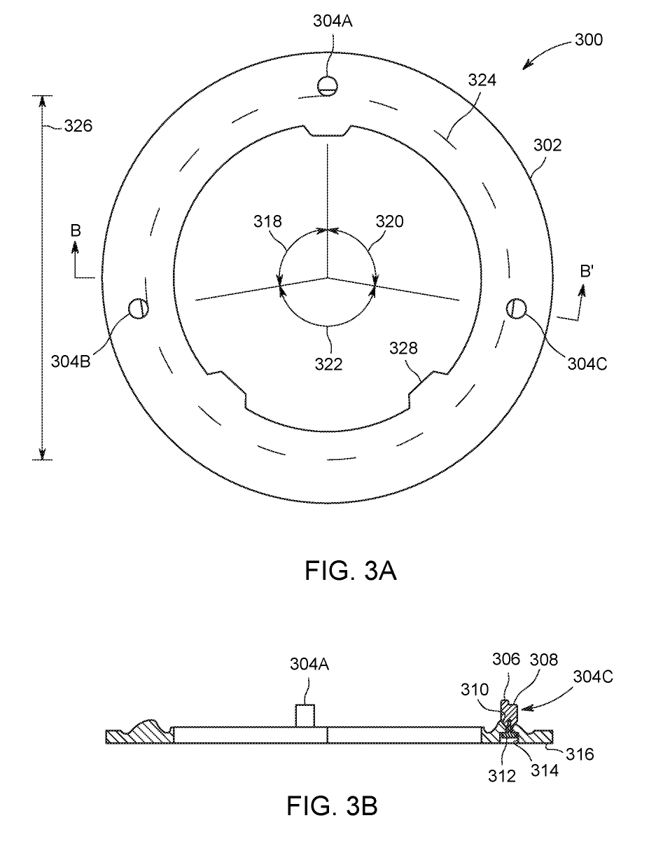

The following description of the deposition ring 300 will be made with reference to FIGS. 3A and 3B. FIG. 3A is a schematic top view of the deposition ring 300 in accordance with some embodiments of the present disclosure. FIG. 3B is a cross-section view of the deposition ring 300 taken along line B-B′. In some embodiments, the deposition ring 300 includes a body 302 and a plurality of protrusions 304A-C (three shown in FIG. 3A) extending upwardly from the body 302. The plurality of protrusions 304A-C are configured to support the shadow ring 200 along the ledge 208. The plurality of protrusions 304A-C are configured so as not to interfere with the processing of a 300 mm substrate. That is, the plurality of protrusions 304A-C are configured to minimize or substantially eliminate any shadowing effect on the 300 mm substrate during deposition by the protrusions.

In some embodiments, each of the plurality of protrusions 304A-C is disposed within a hole 310 formed in the body 302. A shape of the hole 310 corresponds to a shape of the bottom portion of the protrusion. In some embodiments, each protrusion may be fixed to the body 302 via a screw 312 extending through a countersunk hole 314 formed in a bottom surface 316 of the body 302 and threaded into a corresponding threaded hole formed in the bottom of the protrusion. In some embodiments, the plurality of protrusions 304A-C may alternatively be fixed to the body using adhesives. In some embodiments, the body 302 and the plurality of protrusions 304A-C may alternatively be formed as a unitary structure. The plurality of protrusions 304A-C are formed of the same material as the body 302 to minimize or substantially eliminate arcing and thermal expansion mismatch between the plurality of protrusions 304A-C and the body 302.

The plurality of protrusions 304A-C are arranged about a central axis of the deposition ring 300 so that there is enough space between two of the plurality of protrusions 304A-C to allow an end effector of a substrate transfer robot to pass through and lift or place a substrate (e.g., a 300 mm substrate) or the substrate carrier 100. As such, a first angle 318 between a first one of the plurality of protrusions 304A-C (e.g., 304A) and a second one of the plurality of protrusions 304A-C (e.g., 304B) is between about 90° and about 110°. Similarly, a second angle 320 between the first one of the plurality of protrusions 304A-C (e.g., 304A) and a third one of the plurality of protrusions 304A-C (e.g., 304c) is also between about 90° and about 110°. As a result, a third angle 322 between the second and third ones of the plurality of protrusions 304A-C is large enough so that the end effector of the substrate transfer robot can pass between the second and third ones of the plurality of protrusions 304A-C.

A diameter 326 of a circle 324 tangential to and disposed within the plurality of protrusions 304A-C is greater than 300 mm to provide clearance for a 300 mm substrate and the substrate carrier 100 to be placed on a support surface disposed within the deposition ring 300. However, the diameter 326 is less than an outer diameter 210 (see FIG. 2A) of the shadow ring 200 so that the plurality of protrusions 304A-C support the shadow ring 200 along the ledge 208. As depicted in FIG. 3B, in some embodiments, each of the plurality of protrusions 304A-C may also include a step 306 extending upward from an upper surface 308 of the protrusion to minimize a contact area between the protrusions and the shadow ring, thus minimizing or substantially eliminating any particle generation.

In some embodiments, the deposition ring 300 may include a plurality of radially inwardly extending protrusions 328 (three shown in FIG. 3A) that mate with corresponding notches (not shown) in a substrate support on which the deposition ring 300 is disposed to align the deposition ring 300 with the substrate support.

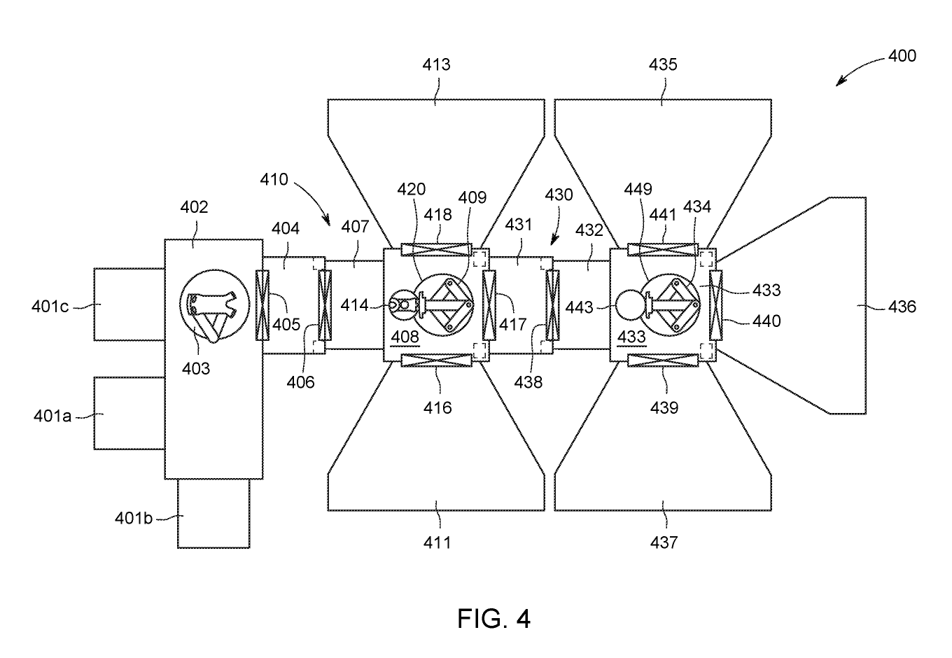

FIG. 4 schematically illustrates a plan view of a non-limiting example of an integrated multi-chamber substrate processing tool 400 having an apparatus for handling substrates of different sizes in accordance with the present disclosure. Examples tools suitable for modification and use in accordance with the present disclosure include the APPLIED CHARGER®, CENTURA®, ENDURA®, and PRODUCER® line of integrated substrate processing tools, available from Applied Materials, Inc., of Santa Clara, Calif. The multi-chamber substrate processing tool 400 comprises multiple processing chambers coupled to a mainframe comprising two transfer chambers (e.g., a transfer chamber 408 and a transfer chamber 433).

The multi-chamber substrate processing tool 400 comprises a front-end environment factory interface (FI) 402 in selective communication with a load lock chamber 404. The multi-chamber substrate processing tool 400 is generally configured to process substrates having a first size (such as a wafer having a first diameter, for example 300 mm, or the like). One or more front opening unified pods (FOUPs), for example FOUP 401a, FOUP 401b, and FOUP 401c, are disposed on or coupled to the FI 402 to provide substrates to or receive substrates from the multi-chamber substrate processing tool 400. In some embodiments, one of the FOUPs is configured to hold substrate carriers (e.g., substrate carrier 100) with substrates having a reduced size (e.g., 200 mm) disposed thereon. In some embodiments, another one of the FOUPs is configured to hold shadow rings (e.g., shadow ring 200).

A factory interface robot 403 is disposed in the FI 402. The factory interface robot 403 is configured to transfer substrates, carriers, and or shadow rings to/from the FOUPs 401a, 401b, and the bridging FOUP 401c, as well as between the bridging FOUP 401c and the load lock chamber 404. In one example of operation, the factory interface robot 403 takes a substrate carrier having a reduced size substrate from FOUP 401a and transfers the carrier holding the substrate to the load lock chamber 404 so that the reduced size substrate can be processed in the multi-chamber substrate processing tool 400.

The load lock chamber 404 provides a vacuum interface between the FI 402 and a first transfer chamber assembly 410. An internal region of the first transfer chamber assembly 410 is typically maintained at a vacuum condition and provides an intermediate region in which to shuttle substrates, or substrate carriers holding substrates, from one chamber to another and/or to a load lock chamber.

In some embodiments, the first transfer chamber assembly 410 is divided into two parts. In some embodiments of the present disclosure, the first transfer chamber assembly 410 comprises the transfer chamber 408 and a vacuum extension chamber 407. The transfer chamber 408 and the vacuum extension chamber 407 are coupled together and in fluid communication with one another. An inner volume of the first transfer chamber assembly 410 is typically maintained at low pressure or vacuum condition during process. The load lock chamber 404 may be connected to the FI 402 and the vacuum extension chamber 407 via slit valves 405 and 406 respectively.

In some embodiments, the transfer chamber 408 may be a polygonal structure having a plurality of sidewalls, a bottom and a lid. The plurality of sidewalls may have openings formed therethrough and are configured to connect with processing chambers, vacuum extension and/or pass through chambers. The transfer chamber 408 shown in FIG. 4 has a square or rectangular shape and is coupled to processing chambers 411, 413, a pass through chamber 431, and the vacuum extension chamber 407. The transfer chamber 408 may be in selective communication with the processing chambers 411, 413, and the pass through chamber 431 via slit valves 416, 418, and 417 respectively.

In some embodiments, a central robot 409 may be mounted in the transfer chamber 408 at a robot port formed on the bottom of the transfer chamber 408. The central robot 409 is disposed in an internal volume 420 of the transfer chamber 408 and is configured to shuttle substrates 414 (or substrate carriers holding substrates) among the processing chambers 411, 413, the pass through chamber 431, and the load lock chamber 404. In some embodiments, the central robot 409 may include two blades for holding substrates, substrate carriers holding reduced size substrates, or shadow rings, each blade mounted on an independently controllable robot arm mounted on the same robot base. In some embodiment, the central robot 409 may have the capacity for vertically moving the blades.

The vacuum extension chamber 407 is configured to provide an interface to a vacuum system to the first transfer chamber assembly 410. In some embodiments, the vacuum extension chamber 407 comprises a bottom, a lid and sidewalls. A pressure modification port may be formed on the bottom of the vacuum extension chamber 407 and is configured to adapt to a vacuuming pump system. Openings are formed on the sidewalls so that the vacuum extension chamber 407 is in fluid communication with the transfer chamber 408, and in selective communication with the load lock chamber 404.

In some embodiments, the vacuum extension chamber 407 comprises a shelf (not shown) configured to store one or more substrates or substrate carriers holding substrates. Processing chambers directly or indirectly connected to the transfer chamber 408 may store their substrates or substrate carriers holding substrates on the shelf and use the central robot 409 to transfer them.

The multi-chamber substrate processing tool 400 can further comprise a second transfer chamber assembly 430 connected to the first transfer chamber assembly 410 by the pass through chamber 431. In some embodiments, the pass through chamber 431, similar to a load lock chamber, is configured to provide an interface between two processing environments. In such embodiments, the pass through chamber 431 provides a vacuum interface between the first transfer chamber assembly 410 and the second transfer chamber assembly 430.

In some embodiments, the second transfer chamber assembly 430 is divided into two parts to minimize the footprint of the multi-chamber substrate processing tool 400. In some embodiments of the present disclosure, the second transfer chamber assembly 430 comprises the transfer chamber 433 and a vacuum extension chamber 432 in fluid communication with one another. An inner volume of the second transfer chamber assembly 430 is typically maintained at low pressure or vacuum condition during processing. The pass through chamber 431 may be connected to the transfer chamber 408 and the vacuum extension chamber 432 via slit valves 417 and 438 respectively so that the pressure within the transfer chamber 408 may be maintained at different vacuum levels.

In some embodiments, the transfer chamber 433 may be a polygonal structure having a plurality of sidewalls, a bottom and a lid. The plurality of sidewalls may have openings formed therein and are configured to connect with processing chambers, vacuum extension and/or pass through chambers. The transfer chamber 433 shown in FIG. 4 has a square or rectangular shape and is coupled with processing chambers 435, 436, 437, and the vacuum extension chamber 432. The transfer chamber 433 may be in selective communication with the processing chambers 435, 436, via slit valves 441, 440, 439 respectively.

A central robot 434 is mounted in the transfer chamber 433 at a robot port formed on the bottom of the transfer chamber 433. The central robot 434 is disposed in an internal volume 449 of the transfer chamber 433 and is configured to shuttle substrates 443 (or substrate carriers holding substrates or shadow rings) among the processing chambers 435, 436, 437, and the pass through chamber 431. In some embodiments, the central robot 434 may include two blades for holding substrates, or holding substrate carriers 132 holding substrates, each blade mounted on an independently controllable robot arm mounted on the same robot base. In some embodiments, the central robot 434 may have the capacity for moving the blades vertically.

In some embodiments, the vacuum extension chamber 432 is configured to provide an interface between a vacuum system and the second transfer chamber assembly 430. In some embodiments, the vacuum extension chamber 432 comprises a bottom, a lid and sidewalls. A pressure modification port may be formed on the bottom of the vacuum extension chamber 432 and is configured to adapt to a vacuum system. Openings are formed through the sidewalls so that the vacuum extension chamber 432 is in fluid communication with the transfer chamber 433, and in selective communication with the pass through chamber 431.

In some embodiments of the present disclosure, the vacuum extension chamber 432 includes a shelf (not shown), similar to that described in connection with the vacuum extension chamber 407 above. Processing chambers directly or indirectly connected to the transfer chamber 433 may store substrates or substrate carriers holding substrates on the shelf.

Typically, substrates are processed in a sealed chamber having a pedestal for supporting a substrate disposed thereon. The pedestal may include a substrate support that has electrodes disposed therein to electrostatically hold the substrate, or hold the substrate carriers holding reduced size substrates, against the substrate support during processing. For processes tolerant of higher chamber pressures, the pedestal may alternately include a substrate support having openings in communication with a vacuum source for securely holding a substrate against the substrate support during processing.

Processes that may be performed in any of the processing chambers 411, 413, 435, 436, or 437, include deposition, implant, and thermal treatment processes, among others. In some embodiments, a processing chamber such as any of the processing chambers 411, 413, 435, 436, or 437, is configured to perform a sputtering process on a substrate, or on multiple substrates simultaneously. In some embodiments, processing chamber 411 is a degas chamber. In some embodiments, the processing chamber 413 is a pre-metallization clean chamber. The pre-metallization clean chamber can use a sputtering clean process comprising an inert gas, such as argon. In some embodiments, the processing chamber 435 is a deposition chamber. The deposition chamber used with embodiments described here can be any known deposition chamber.

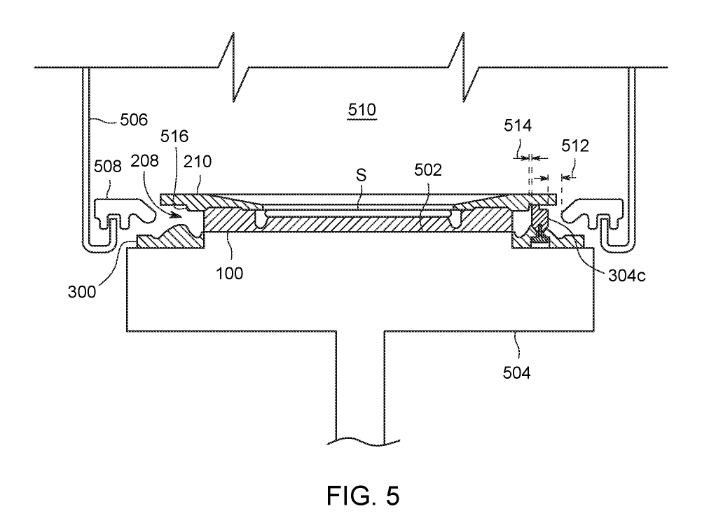

FIG. 5 depicts a schematic cross-sectional view of a processing chamber (e.g., any one of the processing chambers 411, 413, 435, 436, 437) having a process kit in accordance with some embodiments of the present disclosure. As illustrated in FIG. 5, the substrate carrier 100 having the substrate S (i.e., the reduced size substrate) sits atop a support surface 502 of a substrate support 504. The shadow ring 200 rests atop the substrate carrier 100 and the plurality of protrusions 304A-C (only 304C shown in FIG. 5). A process kit having a process kit shield 506 and a cover ring 508 atop a lip of the process kit shield defines a processing volume 510 above the substrate S. In some embodiments, a first radial distance 512 between an inner diameter of the cover ring 508 and the plurality of protrusions 304A-C is between about 1.5 mm and about 2.5 mm. In some embodiments, a second radial distance 514 between an inner wall 516 of the ledge 208 and the plurality of protrusions 304A-C is between about 0.7 mm and about 1.5 mm to compensate for thermal expansion of the shadow ring 200 during processing.

While the foregoing is directed to embodiments of the present disclosure, other and further embodiments of the disclosure may be devised without departing from the basic scope thereof.

1. A process kit, comprising:
a substrate carrier having a pocket configured to hold a substrate, wherein the pocket extends partially through a thickness of the substrate carrier, and wherein the pocket includes an annular trench disposed at a periphery of a floor of the pocket.

2. The process kit of claim 1, wherein a diameter of the pocket is between about 200 mm and about 210 mm.

3. The process kit of claim 1, wherein a depth of the pocket is between about 0.5 mm and about 0.7 mm.

4. The process kit of claim 1, wherein the substrate carrier is formed of monosilicon quartz, ceramic, or silicon carbide.

5. The process kit of claim 1, wherein the substrate carrier includes at least one protrusion extending radially inward into the pocket.

6. The process kit of claim 1, wherein a depth of the annular trench is between about 0.2 mm and about 0.6 mm.

7. The process kit of claim 1, wherein a cross-sectional width of the annular trench is between about 0.8 mm and about 1.2 mm.

8. The process kit of claim 1, wherein the substrate carrier includes an alignment feature that extends into the pocket.

9. A process kit, comprising:
a substrate carrier having a pocket configured to hold a substrate that extends partially through a thickness of the substrate carrier and having an uppermost surface that includes an annular upwardly extending protrusion; and
a shadow ring disposed above the substrate carrier to shield a portion of the substrate carrier radially outward of the pocket and having an annular recess in a lower surface corresponding with the annular upwardly extending protrusion of the substrate carrier, and wherein an inner diameter of the shadow ring is less than an outer diameter of the pocket.

10. The process kit of claim 11, wherein an upper surface of the shadow ring includes a surface disposed at an angle between about 2.5° and about 3.1° from a horizontal plane of the shadow ring.

11. The process kit of claim 11, wherein the pocket includes an annular trench disposed at a periphery of a floor of the pocket having a depth between about 0.2 mm and about 0.6 mm.

12. The process kit of claim 11, wherein the shadow ring includes a ledge disposed radially outward of the annular recess.

13. The process kit of claim 11, wherein the substrate carrier includes at least one protrusion extending radially inward into the pocket.

14. The process kit of claim 11, wherein the shadow ring is formed of quartz or ceramic.

15. The process kit of claim 11, further comprising a deposition ring disposed below the shadow ring and having at least one protrusion for supporting the shadow ring.

16. A processing chamber, comprising:
a substrate support having a support surface;
a substrate carrier disposed atop the support surface, the substrate carrier having a pocket configured to hold a substrate;
a shadow ring disposed atop the substrate carrier to shield a portion of the substrate carrier radially outward of the pocket; and
a process kit having a process kit shield disposed about the substrate carrier and the shadow ring to define a processing volume above the substrate.

17. The processing chamber of claim 16, further comprising a deposition ring disposed below the shadow ring, wherein the shadow ring includes ledge at a radially outward portion and the deposition ring includes a plurality of protrusions that are configured to support the shadow ring along the ledge.

18. The processing chamber of claim 16, wherein the pocket includes an annular trench disposed at a periphery of a floor of the pocket.

19. The processing chamber of claim 16, wherein an inner diameter of the shadow ring is between 0.1 mm and about 0.2 mm less than a diameter of the pocket.

20. The processing chamber of claim 16, wherein an uppermost surface of the substrate carrier is configured to mate with a bottom surface of the shadow ring.
